(19) United States
(12) Patent Application Publication
(10) Pub. No.: US 2024/0122055 A1
(43) Pub. Date: Apr. 11, 2024

(54) ORGANIC SEMICONDUCTING COMPOUND AND ORGANIC OPTOELECTRONIC DEVICES USING THE SAME

(71) Applicant: Raynergy Tek Incorporation, HSINCHU (TW)

(72) Inventors: Yu-Tang Hsiao, HSINCHU (TW); Fang-Ning Li, HSINCHU (TW); Chuang-Yi Liao, HSINCHU (TW)

(21) Appl. No.: 18/368,739

(22) Filed: Sep. 15, 2023

Related U.S. Application Data
(60) Provisional application No. 63/375,923, filed on Sep. 16, 2022.

(51) Int. Cl. H10K 85/10; C09K 11/06; H10K 50/14; H10K 85/40; H10K 85/60

(52) U.S. Cl. CPC H10K 85/113; C09K 11/06; H10K 50/14; H10K 85/40; H10K 85/615; H10K 85/654; H10K 85/6576

(57) ABSTRACT

The present invention relates to an organic semiconducting compound and organic optoelectronic components using the same. The organic semiconducting compound own a novel chemical structure. By using the organic semiconducting compound to prepare organic optoelectronic compounds, environmentally friendly non-halogen solvent can be used. In addition, the photoresponsivity and detectivity are excellent in the near-infrared region.

### BACKGROUND OF THE INVENTION

In recent years, in order to manufacture more versatile and lower-cost electronic components, the demand for organic semiconducting compounds has been increasing. This phenomenon is due to the fact that, compared to traditional semiconductor materials, organic semiconducting compounds have broad light absorption, high light absorption coefficients and adjustable structures. The light absorption range, energy level and solubility can be adjusted according to target requirements. In addition, organic materials have the advantages of low cost, flexibility, low toxicity and large-area production. These advantages make organic optoelectronic materials highly competitive in various fields. Such compounds have a wide range of applications, including organic field-effect transistor (OFET), organic light-emitting diode (OLED), organic photodetector (OPD), organic photovoltaic (OPV) cells, sensors, storage devices and various components of logic circuits. Among them, organic semiconductor materials are usually present in the form of thin films with a thickness of about 50 nm to 1 μm in various components used in the above applications.

Organic photodetector (OPD) is an emerging field of organic optoelectronics in recent years. Such devices can detect various light sources in the environment and are used in various fields such as medical care, health management, smart driving, unmanned aerial vehicles, or digital home. Therefore, there are different material requirements according to the application field. Due to the use of organic materials, the devices have good flexibility. Benefiting from the development of today's materials science, OPD can not only be made into thin films but can also absorb specific wavelength bands. The products currently on the market have different light bands that need to be absorbed depending on the light source. Therefore, the use of organic materials has the ability to adjust the light absorption range and can effectively absorb the required bands to achieve the effect of reducing interference. Besides, the high extinction coefficient of organic materials can also effectively improve detection efficiency. In recent years, the development of OPD has gradually developed from ultraviolet light and visible light to the near infrared region (NIR region).

The active layer material in the organic photodetector directly affects the device performance and therefore plays an important role. The material can be divided into two parts: donor and acceptor. Common donor materials include organic polymers, oligomers, or limited molecular units. Nowadays, the development of D-A (Donor-Acceptor) conjugated polymers is the mainstream. The push-pull electron effect formed by the interaction between units can be used to regulate the energy level and energy gap of the polymer. The corresponding acceptor material is usually a fullerene derivative with high conductivity and light absorption range about between 400 and 600 nm. The acceptor material also includes graphene, metal oxides, or quantum dots.

However, the structure of fullerene derivatives is hard to adjust, and the range of light absorption band and energy level is limited, which limits the overall matching of donor and acceptor materials. With the development of the market, the demand for materials in the near-infrared region is gradually increasing. Even if the light absorption range of the donor material conjugated polymer can be adjusted to the near-infrared region, it may not be able to match well due to the limitation of fullerene acceptors. Therefore, the development of non-fullerene acceptor compounds to replace traditional fullerene acceptors is very important in the breakthrough of active layer materials.

However, the early development of non-fullerene acceptor compounds was quite difficult because the control of the morphology was not easy, so their power conversion efficiency was low. The number of studies on non-fullerene acceptors has boomed since 2015, making their electrical properties significantly improved and becoming a competitive choice. This change is mainly attributed to advances in synthesis methods and improvements in material design strategies. The extensive range of donor materials previously developed for fullerene acceptors has also indirectly contributed to the development of non-fullerene acceptor compounds.

The current development of non-fullerene acceptor compound materials mainly uses an electron-rich center with electron-deficient units on both sides to form a molecule with an A-D-A structure. D is usually a molecule composed of benzene ring and thiophene, and A is usually a cyano-indanone (IC) derivative. Another type of structure is the A′-D-A-D-A′ pattern. As the electron-deficient unit in the center, molecules containing sulfur atoms, nitrogen atoms or selenium atoms are often used to enhance its performance.

In the field of intelligent driving and unmanned aerial vehicles, in order to avoid the interference of visible light with too strong signal, the development trend is to use NIR absorption band; and in order to have better transmittance and long-distance detection properties, the application wavelength needs to exceed 1000 nm. Moreover, in response to the increasing demands in application fields, the optoelectronic devices used need to have higher detection sensitivity and lower dark current.

In addition, in response to the environmental protection regulations of various countries and the requirements for good processing operability, environmentally friendly solvents must be used as much as possible in the material manufacturing process to facilitate wet process operations. However, organic semiconductor materials with relevant potential today including polymers using a donor-acceptor structure or small molecules only have well performance in the light-absorbing range of wavelengths less than 1000 nm. Those with wavelengths greater than 1000 nm have poor performance. In addition, the solvents used in wet processing are mainly halogen-containing organic solvents, which have a great impact on the environment.

Accordingly, it is a problem to be solved by those skilled in the art to develop an organic semiconducting compound that has better responsivity in the infrared range, better electrical performance, and does not need to use halogen-containing organic solvents for processing.

### SUMMARY OF THE INVENTION

An objective of the present invention is to provide an organic semiconducting compound and an organic optoelectronic devices using the same, particularly an n-type organic semiconducting compound. The present invention can overcome the shortcomings of organic semiconducting compounds according to the prior art and provide one or more of the above-mentioned advantageous properties, especially easy synthesis by a method suitable for mass production, excellent responsivity for wavelengths greater than 1000 nm, and good device efficiency, as well as providing good processability and solubility in environmentally friendly solvents in the production process, which is beneficial to large-scale manufacturing using solution processing methods.

Another objective of the present invention is to provide a novel organic optoelectronic device, which comprises the organic semiconducting compound according to the present invention having excellent responsivity for wavelengths greater than 1000 nm, lower dark current, and higher detectivity.

To achieve the above objective, the present invention provides an organic semiconducting compound having the following structure:

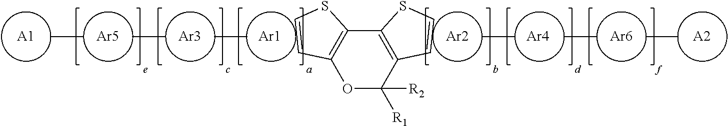

Ar1 and Ar2 are aryl or heteroaryl groups with 5-20 ring atoms, which are monocyclic or fused rings. Ar3 and Ar4 are aryl or heteroaryl groups with 5-20 ring atoms, which are monocyclic or fused rings, and which are substituted by one or more functional group containing heteroatoms. Ar5 and Ar6 are vinyl groups. A1 and A2 are monocyclic or polycyclic groups with 5-20 ring atoms, which contain one or more ketone group and one or more electron-withdrawing group. R₁ and R₂ are selected from the group consisting of C1˜C30 alkyl group, C1˜C30 silyl group, C1˜C30 alkoxy group, C1˜C30 alkylthio group, C1˜C30 haloalkyl group, C2-C30 ester group, C1˜C30 alkylaryl group, C1˜C30 alkyl heteroaryl group, C1˜C30 silylaryl group, C1˜C30 silyl heteroaryl group, C1˜C30 alkoxyaryl group, C1˜C30 alkoxyheteroaryl group, C1˜C30 alkylthioaryl group, C1˜C30 alkylthioheteroaryl group, C1˜C30 haloalkylaryl group, C1˜C30 haloalkylheteroaryl group, C1˜C30 ester aryl group, and C1˜C30 ester heteroaryl group; a and b are selected from 0 or 1, respectively, and a+b≤1. c and d are selected from 1 or 2, respectively. e and f are selected from the integers between 0 and 2, respectively, and e+f≥1.

To achieve another objective as described above, the present invention provides an organic optoelectronic device, which comprises a substrate, an electrode module, and an active layer. The electrode module is disposed on the substrate and includes a first electrode and a second electrode. The active layer is disposed between the first electrode and the second electrode. The material of the active layer includes one or more of the organic semiconducting compounds described in claim 1 or the combination described in claim 7. Wherein, at least one of the first electrode and the second electrode is transparent or semi-transparent.

### BRIEF DESCRIPTION OF DRAWINGS

FIG. 1 shows a structural schematic diagram of the organic optoelectronic device according to a first embodiment of the present invention;

FIG. 2 shows a structural schematic diagram of the organic optoelectronic device according to a second embodiment of the present invention;

FIG. 3 shows a structural schematic diagram of the organic optoelectronic device according to a third embodiment of the present invention;

FIG. 4 shows a structural schematic diagram of the organic optoelectronic device according to a fourth embodiment of the present invention;

FIG. 5 shows a structural schematic diagram of the organic optoelectronic device according to a fifth embodiment of the present invention;

FIG. 6 shows a structural schematic diagram of the organic optoelectronic device according to a sixth embodiment of the present invention;

FIG. 7A shows the experimental result of the absorption spectrum of the organic semiconducting compound N1 according to the present invention;

FIG. 7B shows the experimental result of the absorption spectrum of the organic semiconducting compound N2 according to the present invention;

FIG. 7C shows the experimental result of the absorption spectrum of the organic semiconducting compound N3 according to the present invention; and

FIG. 8 shows the experimental result of the detectivity of the organic optoelectronic device according to the present invention.

### DETAILED DESCRIPTION OF THE INVENTION

The organic semiconductor materials according to the prior art including polymers using a donor-acceptor structure or small molecules, which have well performance in the light-absorbing range of wavelengths less than 1000 nm. Those with wavelengths greater than 1000 nm have poor performance. In addition, the solvents used in wet processing are mainly halogen-containing organic solvents, which have a great impact on the environment.

The advantages of the present invention are that in addition to being easy to synthesize, the organic semiconducting compound according to the present invention does not require the use of halogen-containing organic solvents in the device manufacturing process and exhibits good processability and solubility in solvents during the manufacturing process, which is beneficial to large-scale manufacturing using solution processing methods.

First, the present invention provides an organic semiconducting compound having the following formula:

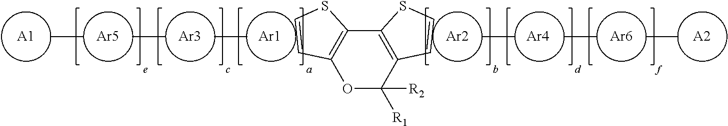

According to the present embodiment, R₁ and R₂ are selected from the group consisting of C1˜C30 alkyl group, C1˜C30 silyl group, C1˜C30 alkoxy group, C1˜C30 alkylthio group, C1˜C30 haloalkyl group, C2˜C30 ester group, C1˜C30 alkylaryl group, C1˜C30 alkyl heteroaryl group, C1˜C30 silylaryl group, C1˜C30 silyl heteroaryl group, C1˜C30 alkoxyaryl group, C1˜C30 alkoxyheteroaryl group, C1˜C30 alkylthioaryl group, C1˜C30 alkylthioheteroaryl group, C1˜C30 haloalkylaryl group, C1˜C30 haloalkylheteroaryl group, C1˜C30 ester aryl group, and C1˜C30 ester heteroaryl group.

Ar1 and Ar2 of the organic semiconducting compound according to the present embodiment are aryl or heteroaryl groups with 5-20 ring atoms, which are monocyclic or fused rings. Ar1 is:

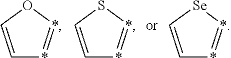

Ar2 is:

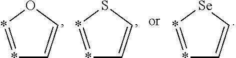

According to the present embodiment, Ar3 and Ar4 are aryl or heteroaryl groups with 5-20 ring atoms, which are monocyclic or fused rings, and which are substituted by one or more functional group containing heteroatoms. Ar3 and Ar4 are:

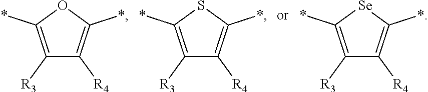

R₃ and R₄ are selected from the group consisting of H, C1˜C30 silyl group, C1˜C30 alkoxy group, C1˜C30 alkylthio group, C1˜C30 haloalkyl group, C2˜C30 ester group, C1˜C30 alkylaryl group, C1˜C30 alkyl heteroaryl group, C1˜C30 silylaryl group, C1˜C30 silyl heteroaryl group, C1˜C30 alkoxyaryl group, C1˜C30 alkoxyheteroaryl group, C1˜C30 alkylthioaryl group, C1˜C30 alkylthioheteroaryl group, C1˜C30 haloalkylaryl group, C1˜C30 haloalkylheteroaryl group, C1˜C30 ester aryl group, and C1˜C30 ester heteroaryl group, wherein at least one of R₃ and R₄ is not H.

Furthermore, “heteroatoms” in the present embodiment should be understood as atoms in organic compounds that are not H or C atoms, and preferably should be understood as referring to B, N, O , S, P, Si, Se, As, Te, or Ge.

According to the present embodiment, Ar5 and Ar6 are vinyl groups.

According to the present embodiment, A1 and A2 are monocyclic or polycyclic group withs 5-20 ring atoms, which has one or more ketone group and one or more electron-withdrawing group. A1 and A2 are selected, respectively, from the group consisting of:

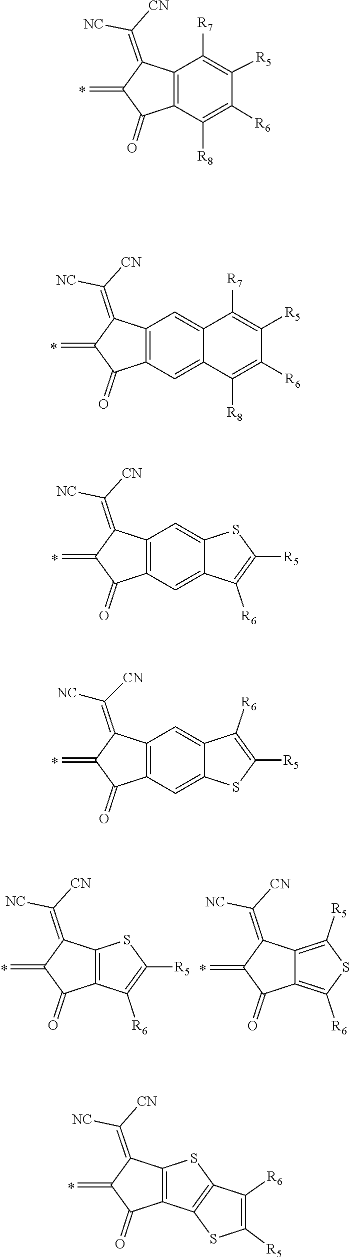

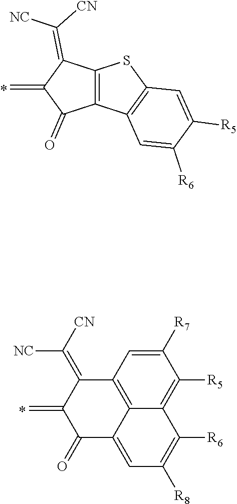

R₅, R₆, R₇, and R₈ are selected from the group consisting of C1˜C30 alkyl group, C1˜C30 silyl group, C1˜C30 alkoxy group, C1˜C30 alkylthio group, C1˜C30 haloalkyl group, halogen, hydrogen atom, cyano group, and respectively.

According to the present embodiment, a and b are selected from 0 or 1, respectively, and a+b≤1.

According to the present embodiment, c and d are selected from 1 or 2, respectively.

According to the present embodiment, e and f are selected from the integers between 0 and 2, respectively, and e+f≥1.

The organic semiconducting compound according to the present embodiment is selected from the group consisting of:

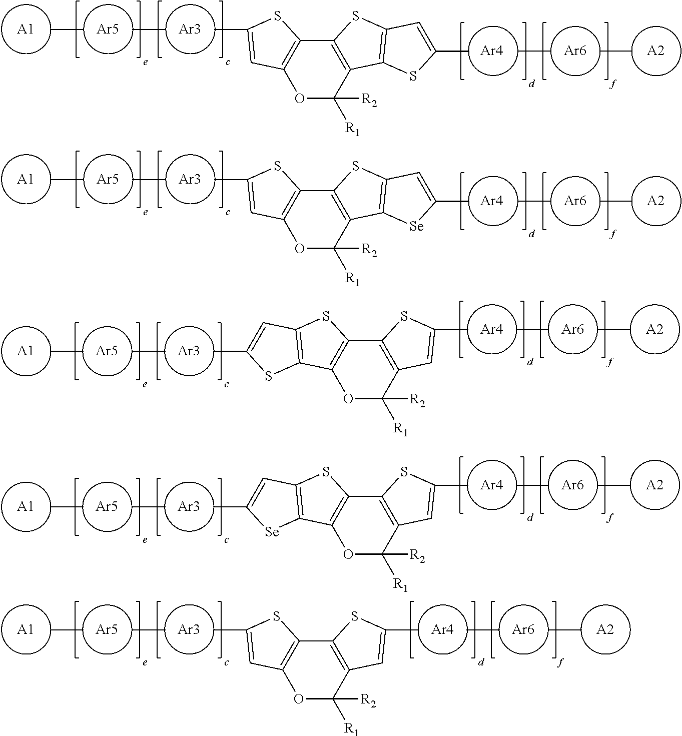

In the following, the preparation method of the organic semiconducting compound according to the present invention will be illustrated by examples.

The preparation for N1 is described as follows:

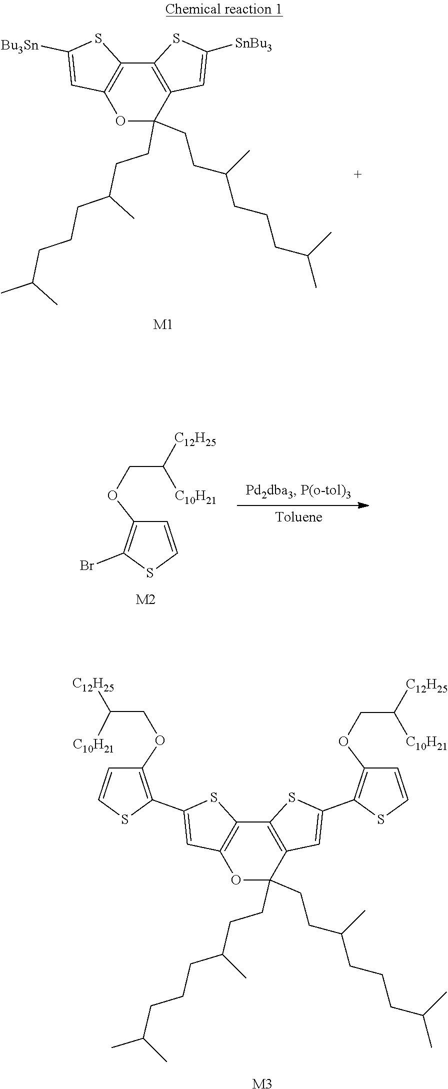

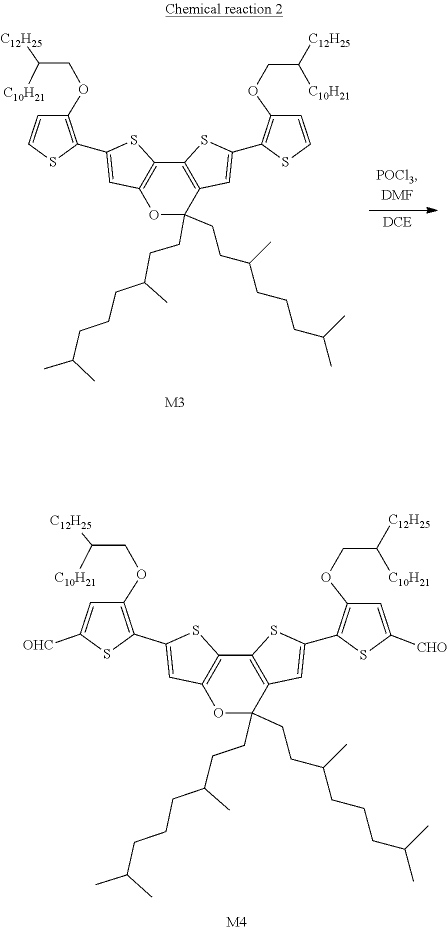

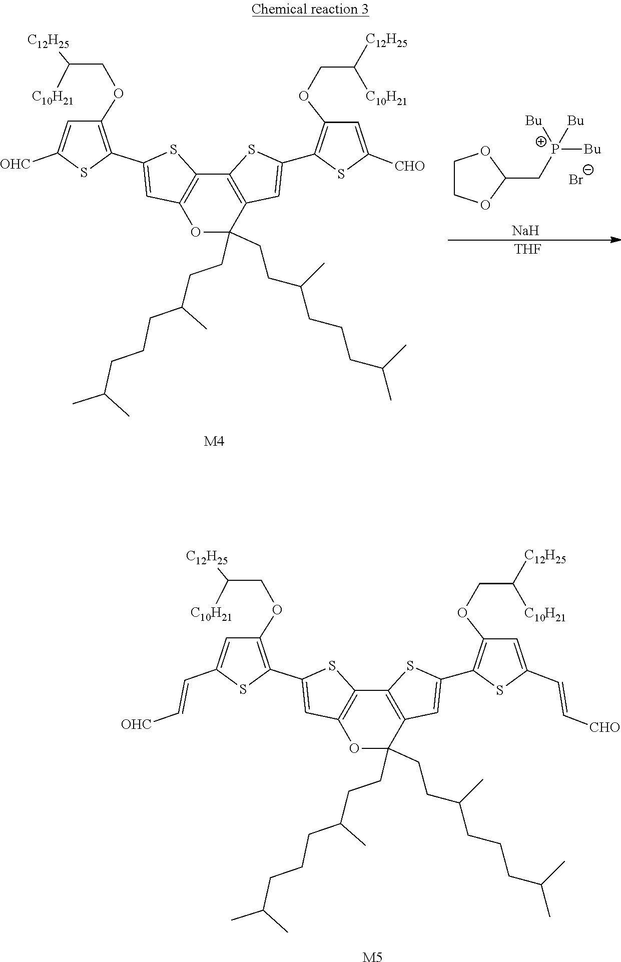

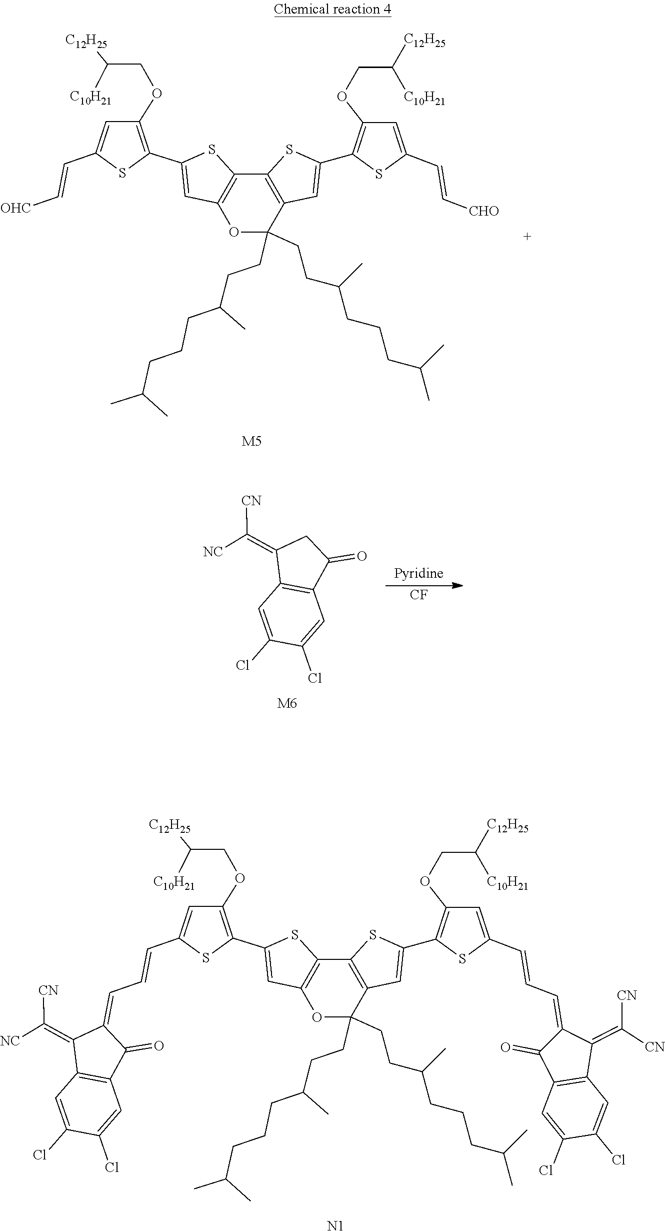

First, the reaction of Chemical reaction 1 is as follows:

Prepare a 100 ml three-neck flask. M1 (1 g, 0.95 mmol) and M2 (1.2 g, 2.4 mmol) were added into three-neck flask. Added toluene (30 mL) and stirred with a magnet. The reaction was deoxygenated at room temperature for 30 minutes then added tris(dibenzylideneacetone)dipalladium (Pd₂dba₃, 34 mg, 0.038 mmol) and tris(o-methylphenyl)phosphine (P(o-tolyl)_{3pb , 46} mg, 0.152 mmol). Heated up the reaction to 60° C. for 24 hours. The reaction was cooled to the room temperature. Silica gel column chromatography was used (the eluent was heptane/dichloromethane=9/1) to obtain the product as a green oil M3 (1.1 g, 86%). ¹H NMR (500 MHz, CDCl₃): δ 7.11-6.98 (m, 2H), 6.88-6.69 (m, 4H), 4.08-4.00 (m, 4H), 2.04-1.82 (m, 6H), 1.50-1.41 (m, 12H), 1.39-1.21 (m, 88H), 0.89-0.81 (m, 30H).

The reaction of Chemical reaction 2 is as follows:

Prepare a 100 ml double-necked flask and place it in an ice bath. Phosphorus oxychloride (POCl₃, 0.75 g, 4.91 mmol) and dimethylformamide (DMF, 3.17 mL, 40.9 mmol) were added and stirred with a magnet for 30 minutes to form a Vilsmeier reagent. Prepared another 100 ml double-necked flask. M3 (1.1 g, 0.818 mmol) and dichloroethane (DCE, 50 mL) were added, then stirred with a magnet. Then added the Vilsmeier reagent. Heated up the reaction to 60° C. for 18 hours. The reaction was cooled to the room temperature. Extract three times with dichloromethane/water. The organic layer was collected and dried with magnesium sulfate to remove water. The solvent was removed and purified using silica gel column chromatography (the eluent was heptane/chloroform=1/1) to obtain the product as a green oil M4 (900 mg, 76%). ¹H NMR (500 MHz, CDCl₃): δ9.75 (s, 2H), 7.46 (s, 1H), 7.45 (s, 1H), 7.09 (s, 1H), 7.05 (s, 1H), 4.08 (d, J=5.5 Hz, 4H), 1.91-1.88 (m, 6H), 1.49-1.37 (m, 12H), 1.30-1.22 (m, 88H), 0.89-0.80 (m, 30H).

The reaction of Chemical reaction 3 is as follows:

Prepare a 100 ml three-neck flask. M4 (900 mg, 0.646 mmol), tributyl(1,3-dioxolan-2-ylmethyl)phosphonium bromide (950 mg, 2.57 mmol), sodium hydride (NaH, 93 mg, 3.86 mmol) and add anhydrous tetrahydrofuran (THF, 30 mL) were added. The reaction was stirred for 18 hours. Add dilute hydrochloric acid (10%, 3 mL) in an ice bath. and react for 30 minutes. Extract three times with ethyl acetate/water. The organic layer was collected and dried with magnesium sulfate to remove water. The solvent was removed and purified using silica column chromatography (the eluent was heptane/chloroform=1/2) to obtain the product as a purple oil M5 (680 mg, 73%). ¹H NMR (500 MHz, CDCl₃): δ9.60 (d, J=7.5 Hz, 2H), 7.42 (d, J=4.0 Hz, 1H), 7.39 (d, J=4.0 Hz,1H), 7.07 (s, 1H), 7.06 (s, 1H), 6.97 (s, 1H), 6.88 (s, 1H), 6.47-6.41 (m, 2H), 4.04 (d, J=5.0 Hz, 4H), 1.93-1.84 (m, 6H), 1.48-1.43 (m, 12H), 1.36-1.07 (m, 88H), 0.87-0.80 (m, 30H).

The reaction of Chemical reaction 4 is as follows:

Take a 100 ml three-neck flask. M5 (360 mg, 0.248 mmol), M6 (261 mg, 0.991 mmol), and chloroform (CF, 10 mL) were added and stirred with a magnet. The reaction was deoxygenated with argon for 30 minutes. Added pyridine (0.15 mL) in an ice bath and reacted for 1 hour. Added methanol to precipitate the product. Collected the solid by suction filtration, and used silica gel column chromatography (the eluent was heptane/chloroform=1/2) to obtain the product as a blue-black solid N1 (270 mg, 56%). ¹H NMR (500 MHz, CDCl₃): δ 8.71 (s, 1H), 8.66 (s, 1H), 8.46-8.40 (m, 1H), 8.37-8.36 (m, 2H), 8.29 (d, J=12.0 Hz, 1H), 7.88 (s, 1H), 7.88 (s, 1H), 7.36-7.33 (m, 1H), 7.23 (d, J=14.5 Hz, 1H), 7.13-7.11 (m, 3H), 6.89 (s, 1H), 4.14-4.11 (m, 4H), 2.02-1.90 (m, 6H), 1.68-1.09 (m, 100H), 0.89-0.82 (m, 30H).

The preparation for N2 is described as follows:

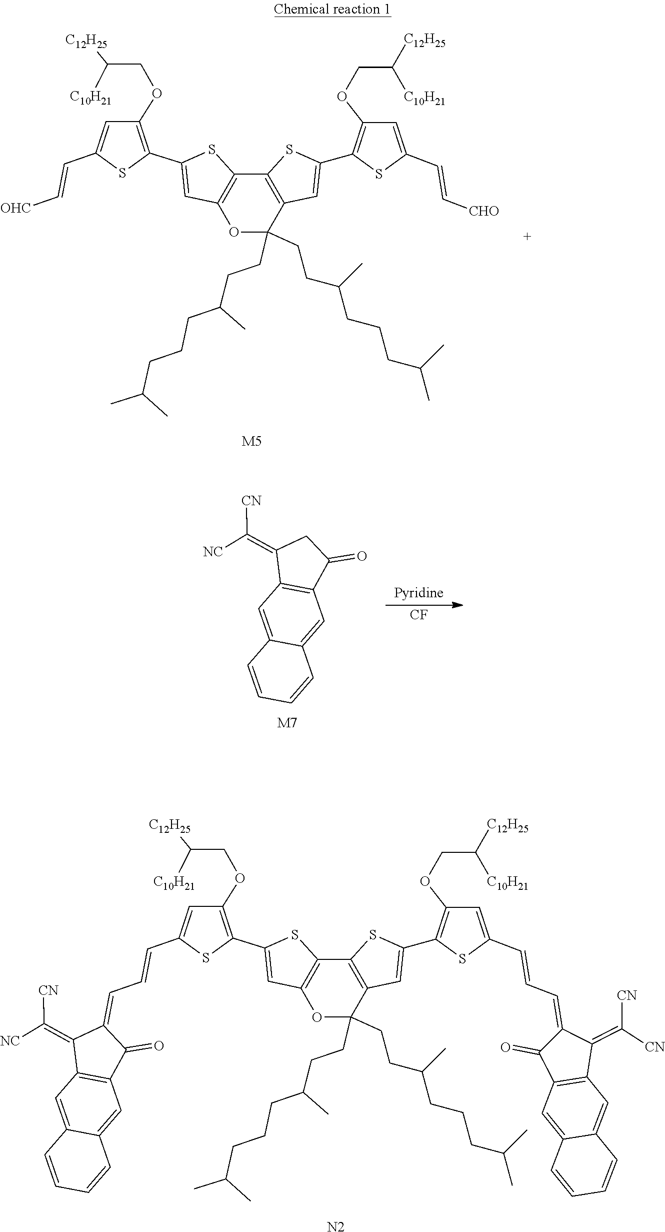

The reaction of Chemical reaction 1 for N2 is as follows:

Take a 100 ml three-neck flask. M5 (160 mg, 0.110 mmol), M7 (108 mg, 0.441 mmol), and chloroform (CF, 10 mL) were added and stirred with a magnet. The reaction was deoxygenated with argon for 30 minutes. Added pyridine (0.15 mL) in an ice bath and reacted for 1 hour. Added methanol to precipitate the product. Collected the solid by suction filtration, and used silica gel column chromatography (the eluent was heptane/chloroform=1/1) to obtain the product as a blue-black solid N2 (100 mg, 48%). ¹H NMR (500 MHz, CDCl₃): δ 9.13 (s, 1H), 9.12 (s, 1H), 8.68-8.62 (m, 2H), 8.44-8.41 (m, 2H), 8.34 (s, 1H), 8.31 (s, 1H), 8.07-8.00 (m, 4H), 7.71-7.64 (m, 4H), 7.37-7.29 (m, 2H), 7.17-7.13 (m, 3H), 6.95 (s, 1H), 4.14-4.12 (m, 4H), 1.96-1.91 (m, 6H), 1.62-1.07 (m, 100H), 0.89-0.79 (m, 30H).

The preparation for N3 is described as follows:

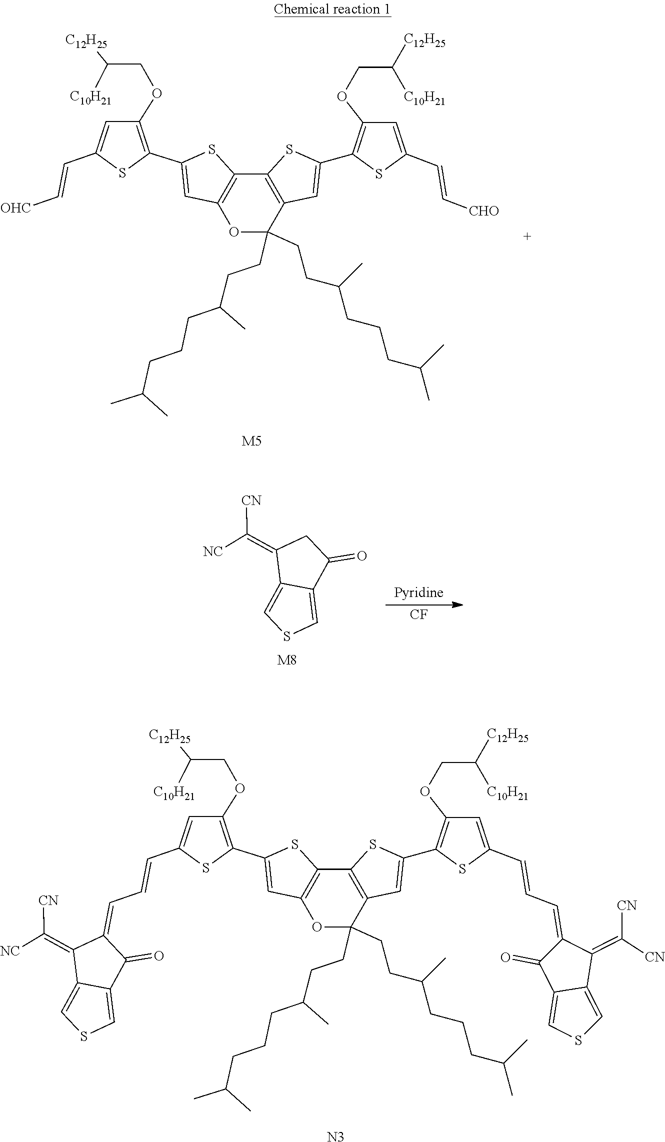

The reaction of Chemical reaction 1 for N3 is as follows:

Take a 100 ml three-neck flask. M5 (160 mg, 0.110 mmol), M8 (88 mg, 0.441 mmol), and chloroform (CF, 10 mL) were added and stirred with a magnet. The reaction was deoxygenated with argon for 30 minutes. Added pyridine (0.15 mL) in an ice bath and reacted for 1 hour. Added methanol to precipitate the product. Collected the solid by suction filtration, and used silica gel column chromatography (the eluant was heptane/chloroform=1/1) to obtain the product as a blue-black solid N3 (100 mg, 48%). ¹H NMR (500 MHz, CDCl₃): δ 8.56-8.49 (m, 2H), 8.35-8.31 (m, 4H), 7.91 (dd, J=8.0 Hz, J=2.5 Hz, 2H), 7.35 (d, J=12.0 Hz, 1H), 7.32 (d, J=12.5 Hz, 1H), 7.15 (d, J=8.5 Hz, 2H), 7.09 (s, 1H), 6.97 (s, 1H), 4.10 (d, J=5.0 Hz, 4H), 1.98-1.87 (m, 6H), 1.59-1.10 (m, 100H), 0.86-0.82 (m, 30H).

The embodiment of the organic semiconducting compound according to the present invention is shown in Table 1.

TABLE 1
Embodiment of the organic semiconducting compound according to the
present invention

| | |
|---|---|
| 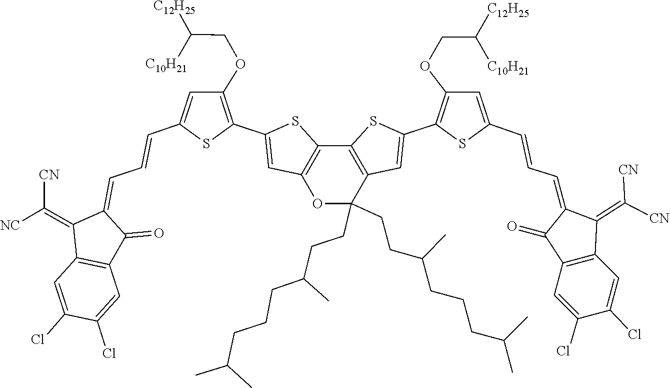 | N1 |
| 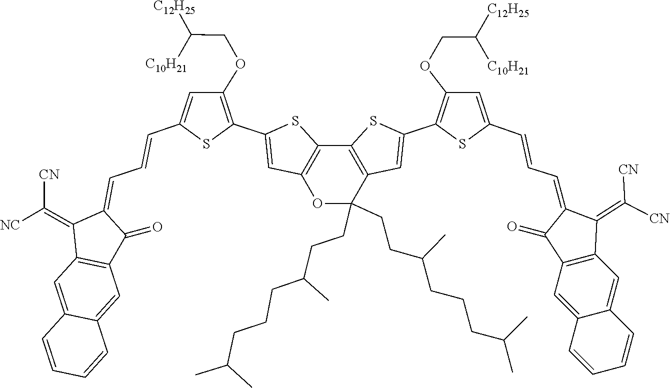 | N2 |
| 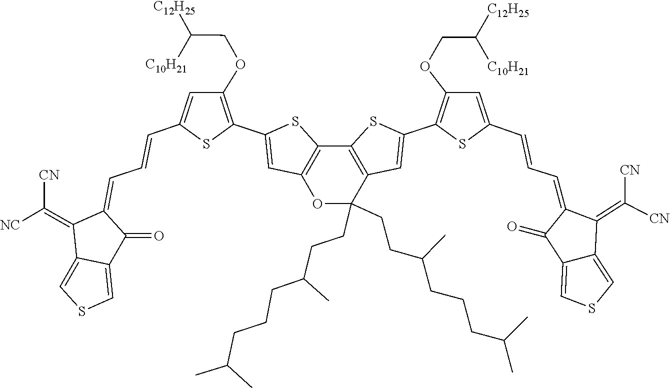 | N3 |
| 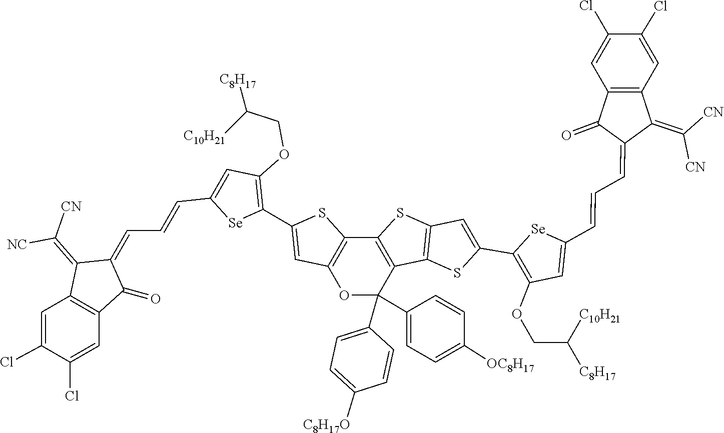 | N4 |
| 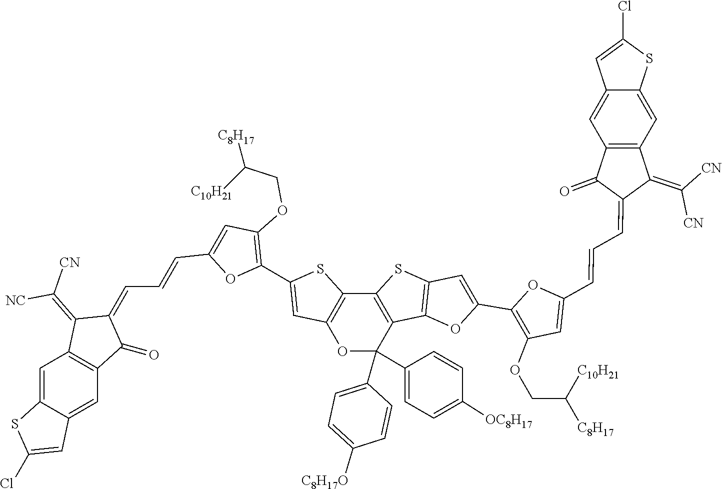 | N5 |
| 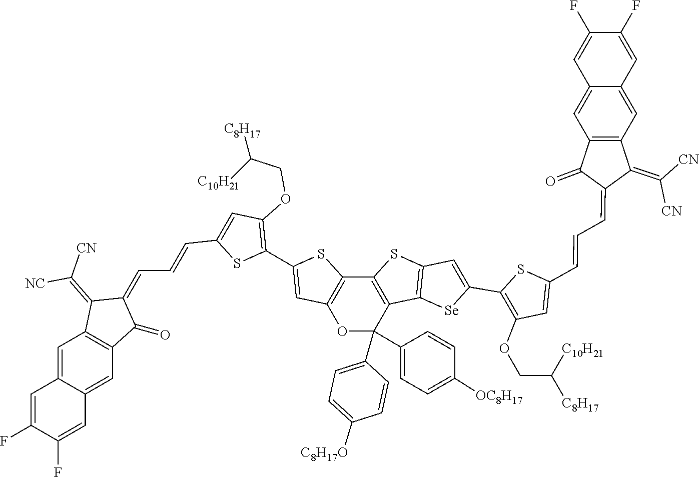 | N6 |
| 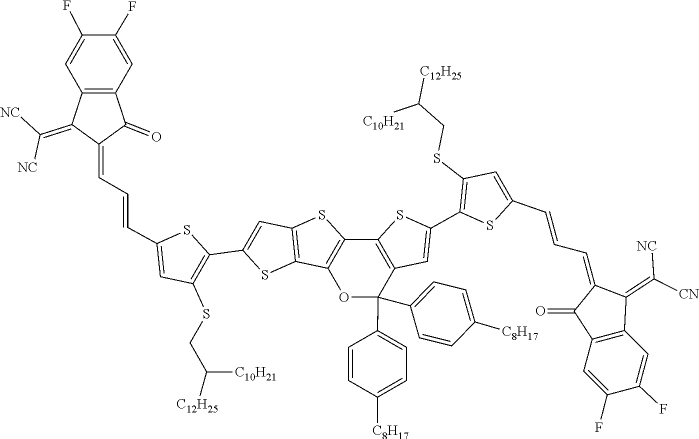 | N7 |
| 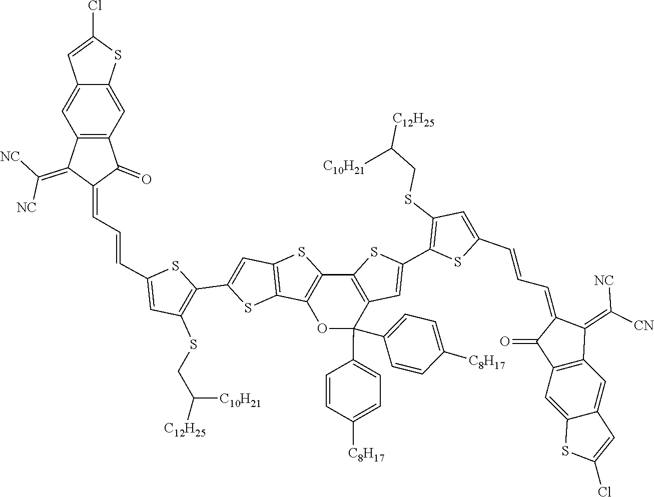 | N8 |
| 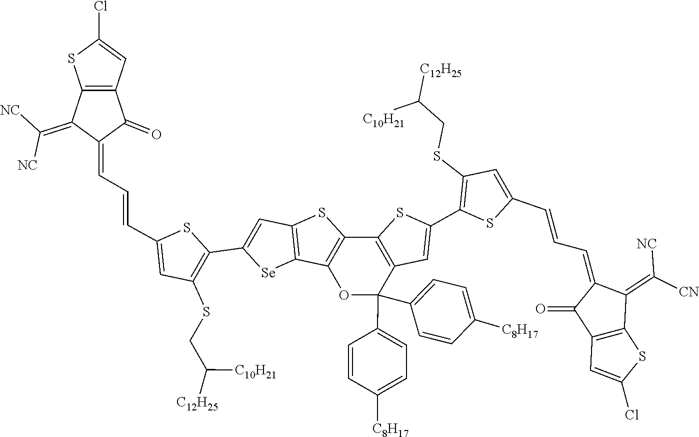 | N9 |
| 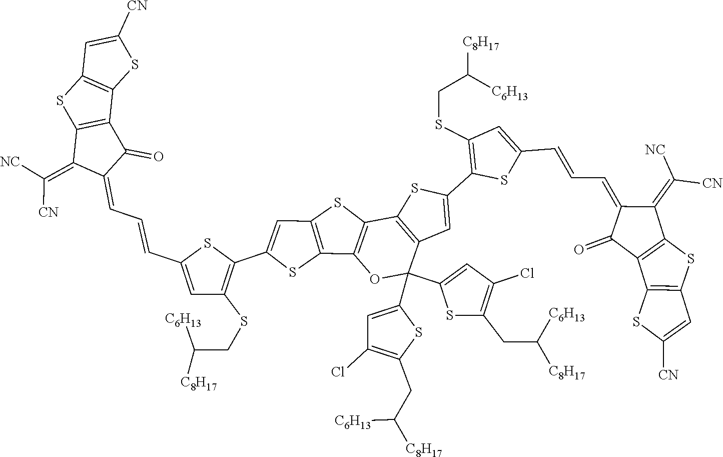 | N10 |
| 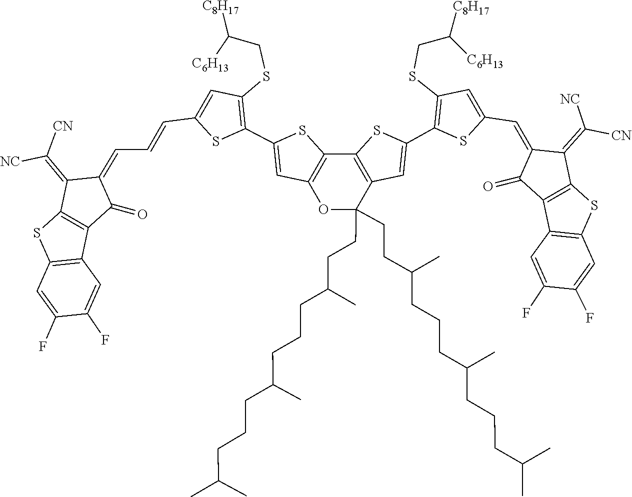 | N11 |

Furthermore, the organic semiconducting compound according to the present invention is used as a charge transport, semiconducting, conductive, photoconductive, or light-emitting material in optical, electro-optical, electronic, electroluminescent, or photovoltaic components or devices. In these components or devices, the organic semiconducting compound according to the present invention is usually used as a thin layer or film.

The organic semiconducting compound according to the present invention is further suitable as an electron acceptor or n-type semiconductor for organic optoelectronic devices, and is suitable for preparing dopants of n-type and p-type semiconductors for use in organic photodetector devices and other fields. The term “n-type” or “n-type semiconductor” will be understood to refer to a doped semiconductor in which the density of conducting electrons exceeds the density of holes, and the term “p-type” or “p-type semiconductor” will be understood to refer to a doped semiconductor in which the density of holes exceeds the density of conducting electrons. (Refer to J. Thewlis, Concise Dictionary of Physics, Pergamon Press, Oxford, 1973)

When the organic semiconducting compound according to the present invention is to be processed, it is necessary to add one or more small molecule compound and/or polymer with charge transport, semiconducting, conductive, photoconductive, hole blocking, and electron blocking properties then mixed to form the first composition.

Furthermore, the organic semiconducting compound according to the present invention can be mixed with one or more organic solvents. These organic solvents are preferably aliphatic hydrocarbons, chlorinated hydrocarbons, aromatic hydrocarbons, ketones, ethers, and mixtures thereof, and more preferably toluene, o-xylene, p-xylene, 1,3,5-trimethylbenzene or 1,2,4-trimethylbenzene, tetrahydrofuran, or 2-methyltetrahydrofuran.

The organic semiconducting compounds according to the present invention may also be used in patterned OSC layers in devices as described herein. For modern microelectronics applications, it is generally desirable to produce small structures or patterns to reduce cost (more device/unit area) and power consumption. Patterning of thin layers including the organic semiconducting compounds according to the present invention can be performed, for example, by photolithography, electron beam etching techniques, or laser patterning.

For use as a thin layer in electronic or electro-optical devices, the first composition or the second composition composed of an organic semiconducting compound according to the present invention can be deposited by any suitable method. Wet process of the device is better than the vacuum deposition technology. The second composition composed of the organic semiconducting compound according to the present invention can make the use of several liquid coating techniques feasible.

Preferred deposition techniques include, but not limited to, dip coating, spin coating, inkjet printing, nozzle printing, letterpress printing, screen printing, gravure printing, blade coating, roller printing, reverse roller printing, planographic printing, dry planographic printing, quick-drying printing, web printing, spray coating, curtain coating, brush coating, slot-dye coating, or pad printing.

In addition, the present invention is combined to form a composition, which includes an n-type organic semiconducting compound and a p-type organic semiconducting compound. The n-type organic semiconducting compound is the organic semiconducting compound as described in claim 1, and the p-type organic semiconducting compound is a polymer.

The p-type semiconducting compound is selected from the group consisting of:

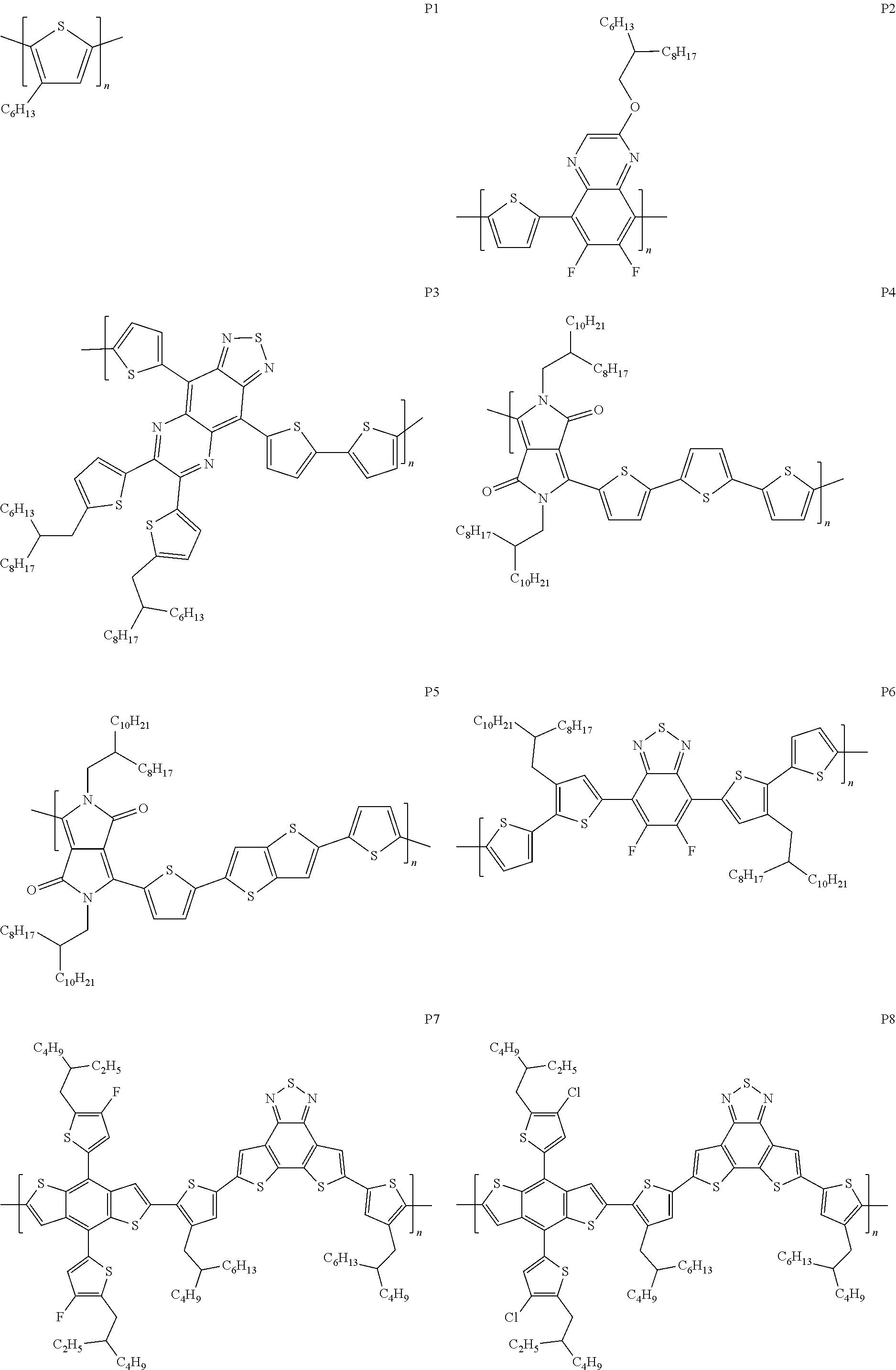

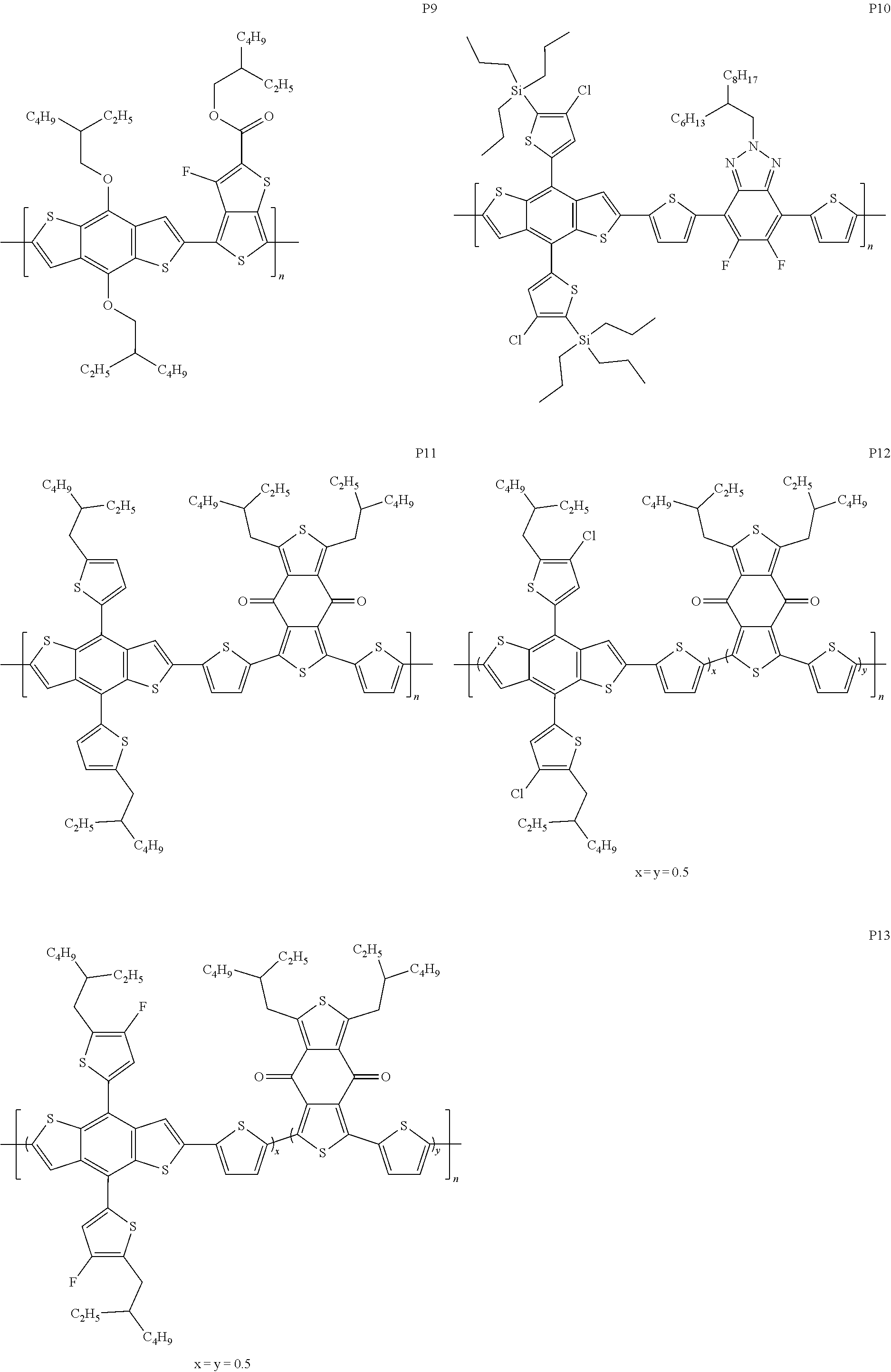

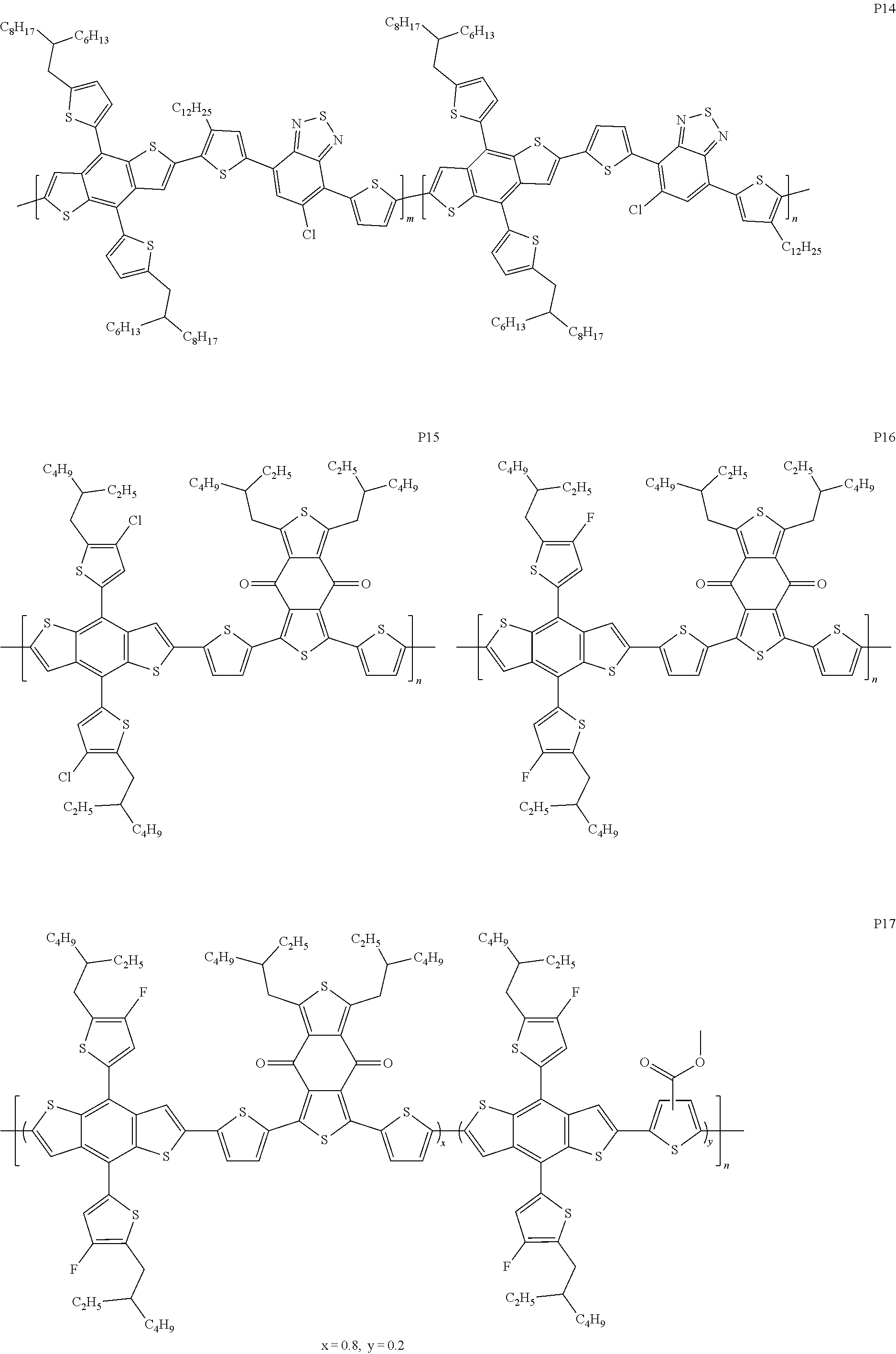

According to the present invention, the coefficients m and n are integers >0.

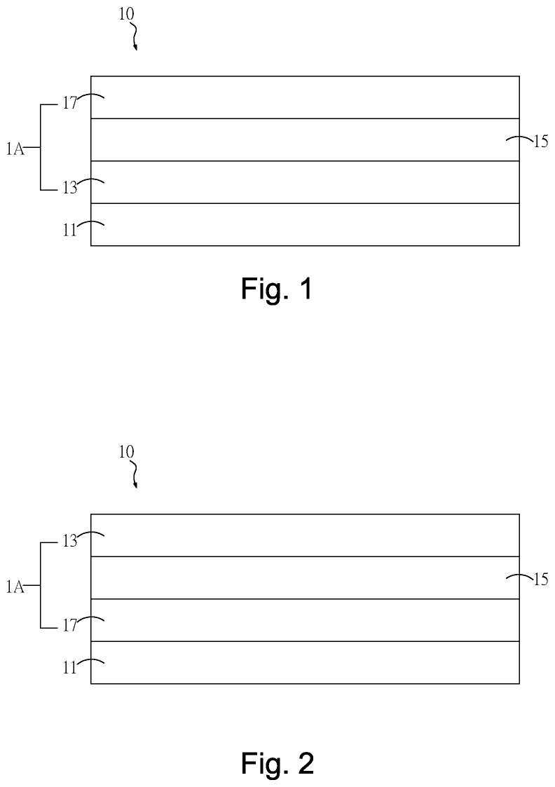

Besides, please refer to FIG. 1, which shows a structural schematic diagram of the organic optoelectronic device according to a first embodiment of the present invention. As shown in the figure, the present invention also provides an organic optoelectronic device 10 containing the organic semiconducting compound and comprising a substrate 11, an electrode module 1A, and an active layer 15.

According to the present embodiment, the electrode module lA is disposed on the substrate 11. The electrode module lA includes a first electrode 13 and a second electrode 17. The active layer 15 is disposed between the first electrode 13 and the second electrode 17.

The material of the active layer 15 includes one or more of the organic semiconducting compounds described in claim 1 or the composition described in claim 7.

According to the present embodiment, the first electrode 13, the active layer 15, and the second electrode 17 are disposed sequentially from the bottom up on the substrate 11. In other words, the first electrode 13 is disposed on the substrate 11; the active layer 15 is disposed on the first electrode 13; and the second electrode 17 is disposed on the active layer 15.

The above-mentioned substrate 11 is preferably a glass substrate or a transparent flexible substrate that has mechanical strength, thermal strength, and transparency. The material of the transparent flexible substrate can be polyethylene, ethylene-vinyl acetate copolymer, ethylene-vinyl alcohol copolymer, polypropylene, polystyrene, polymethyl methacrylate, polyvinyl chloride, polyvinyl alcohol, poly vinyl butyraldehyde, nylon, polyether ether ketone, polysulfone, poly(ether sulfones), tetrafluoroethylene-perfluoroalkyl vinyl ether copolymer, polyfluoroethylene, tetrafluoroethylene-ethylene copolymer, tetrafluoroethylene-hexafluoroethylene fluoropropylene copolymer, polychlorotrifluoroethylene, polyvinylidene fluoride, polyester, polycarbonate, polyurethane, polyimide.

According to the present embodiment, at least one of the first electrode 13 and the second electrode 17 is transparent or semi-transparent.

According to the present embodiment, the material of the first electrode 13 as described above is selected from the group consisting of indium oxide doped or undoped with halogen, doped or undoped tin oxide, indium tin oxide, and indium zinc oxide.

According to the present embodiment, the material of the second electrode 17 is selected from the group consisting of metal oxides, metals, conductive polymer, carbon-base conductors, and metal compounds.

Next, please refer to FIG. 2, which shows a structural schematic diagram of the organic optoelectronic device according to a second embodiment of the present invention. The figure shows the connection relation among the organic optoelectronic device 10, the substrate 11, the electrode module 1A, and the active layer 15. The materials of the substrate 11, the first electrode 13, the active layer 15, and the second electrode 17 are the same as those in the previous embodiment (the first embodiment). Hence, the details will not be repeated.

According to the present embodiment, the second electrode 17, the active layer 15, and the first electrode 13 are disposed sequentially from the bottom up on the substrate 11.

According to the present embodiment, the second electrode 17 is disposed on the substrate 11; the active layer 15 is disposed on the second electrode 17; and the first electrode 13 is disposed on the active layer 15.

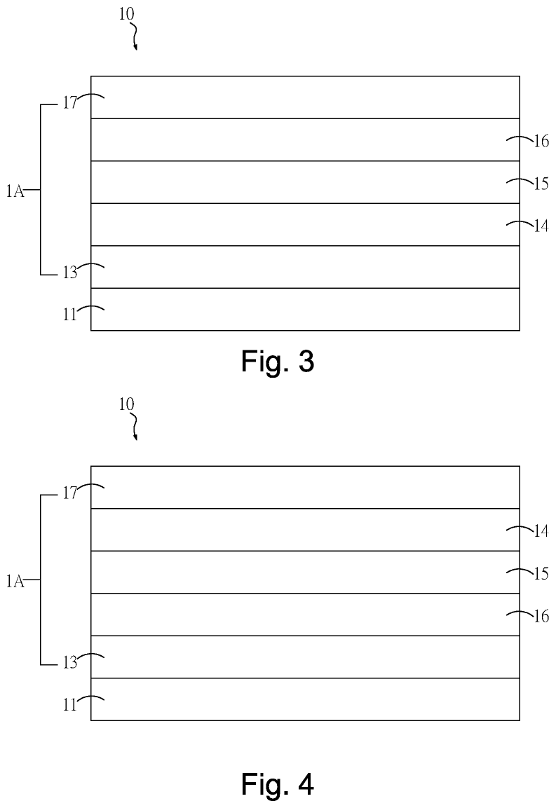

Next, please refer to FIG. 3, which shows a structural schematic diagram of the organic optoelectronic device according to a third embodiment of the present invention. The figure shows the connection relation among the organic optoelectronic device 10, the substrate 11, the electrode module 1A, and the active layer 15. The materials of the substrate 11, the first electrode 13, the active layer 15, and the second electrode 17 are the same as those in the first embodiment. Hence, the details will not be repeated.

According to the present embodiment, the first electrode 13 is disposed on the substrate 11; the active layer 15 is disposed on the first electrode 13; and the second electrode 17 is disposed on the active layer 15.

Moreover, the present embodiment further comprises a first carrier transport layer 14 and a second carrier transport layer 16. The first carrier transport layer 14 is disposed between the first electrode 13 and the active layer 15. The second carrier transport layer 16 is disposed between the active layer 15 and the second electrode 17.

According to the present embodiment, the material of the first carrier transport layer 14 is selected from conjugated polymer electrolytes, such as PEDOT:PSS; or polymer acids, such as polyacrylate; or conjugated polymers, such as polytriarylamine (PTAA); or insulating polymers, such as Nafi film, polyethyleneimine, or polystyrene sulfonate; or polymers doped with metal oxides, these metal oxide such as MoOx, NiOx, WOx, SnOx; or metal oxides, such as MoOx, NiOx, WOx, SnOx; or organic small molecule compounds, such as N,N′-diphenyl-N,N′-bis(1-naphthyl) (1,1′-biphenyl)benzene)-4,4′-diamine (NPB), N,N′-diphenyl-N,N′-(3-methylphenyl)-1,1′-biphenyl-4,4′-diamine (TPD); or a combination of one or more of the above materials. The material of the second carrier transport layer 16 is selected from conjugated polymer electrolytes, such as polyethyleneimine; or conjugated polymers, such as poly[3-(6-trimethylammoniumhexyl)thiophene], poly(9,9)-bis(2-ethylhexyl-fluorene)-b-poly[3 -(6-trimethylammonohexyl)thiophene] or poly [(9,9-bis(3′- (N,N-dimethylamino)propyl)-2,7-fluorene)-alt-2,7-(9,9-dioctylfluorene)]; organic small molecule compounds, such as tris(8-quinolyl)-aluminum(III)(Alq3), 4,7-diphenyl-1,10-phenanthroline; metal oxides such as ZnOx, aluminum-doped ZnO (AZO), TiOx or nanoparticles thereof; or salts, such as LiF, NaF, CsF, CsCO₃; or amines, such as primary, secondary, or tertiary amines; or a combination of one or more of the above materials.

Next, please refer to FIG. 4 shows a structural schematic diagram of the organic optoelectronic device according to a fourth embodiment of the present invention. The figure shows the connection relation among the organic optoelectronic device 10, the substrate 11, the electrode module 1A, and the active layer 15. The materials of the substrate 11, the first electrode 13, the active layer 15, and the second electrode 17 are the same as those in the first embodiment. The materials of the first carrier transport layer 14 and the second carrier transport layer 16 are the same as those in the previous embodiment (the third embodiment). Hence, the details will not be repeated.

According to the present embodiment, the first electrode 13 is disposed on the substrate 11; the active layer 15 is disposed on the first electrode 13; and the second electrode 17 is disposed on the active layer 15. The first carrier transport layer 14 is disposed between the second electrode 17 and the active layer 15. The second carrier transport layer 16 is disposed between the active layer 15 and the first electrode 13.

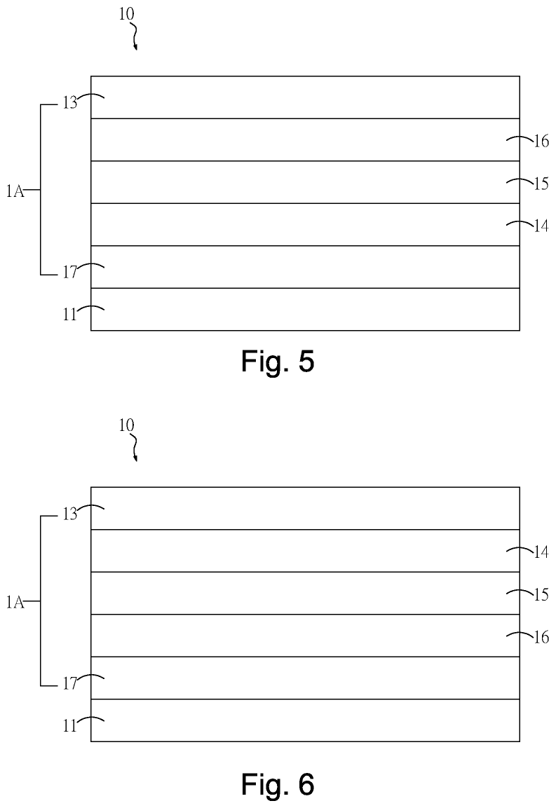

Next, please refer to FIG. 5, which shows a structural schematic diagram of the organic optoelectronic device according to a fifth embodiment of the present invention. The figure shows the connection relation among the organic optoelectronic device 10, the substrate 11, the electrode module 1A, and the active layer 15. The materials of the substrate 11, the first electrode 13, the active layer 15, and the second electrode 17 are the same as those in the first embodiment. The materials of the first carrier transport layer 14 and the second carrier transport layer 16 are the same as those in the third embodiment. Hence, the details will not be repeated.

According to the present embodiment, the second electrode 17 is disposed on the substrate 11; the active layer 15 is disposed on the second electrode 17; and the first electrode 13 is disposed on the active layer 15. The first carrier transport layer 14 is disposed between the second electrode 17 and the active layer 15. The second carrier transport layer 16 is disposed between the active layer 15 and the first electrode 13. Next, please refer to FIG. 6, which shows a structural schematic diagram of the organic optoelectronic device according to a sixth embodiment of the present invention.

The figure shows the connection relation among the organic optoelectronic device 10, the substrate 11, the electrode module 1A, and the active layer 15. The materials of the substrate 11, the first electrode 13, the active layer 15, and the second electrode 17 are the same as those in the first embodiment. The materials of the first carrier transport layer 14 and the second carrier transport layer 16 are the same as those in the third embodiment. Hence, the details will not be repeated.

According to the present embodiment, the second electrode 17 is disposed on the substrate 11; the active layer 15 is disposed on the second electrode 17; and the first electrode 13 is disposed on the active layer 15. The second carrier transport layer 16 is disposed between the second electrode 17 and the active layer 15. The first carrier transport layer 14 is disposed between the active layer 15 and the first electrode 13. Next, in order to illustrate the efficiency improvement brought about by the application of the organic semiconducting compound according to the present invention to organic optoelectronic devices, the organic optoelectronic devices containing the organic semiconducting compound according to the present invention will be prepared for property testing and efficacy performance. The test results are as follows:

The testing method for the absorption spectrum of materials will be described as follows below:

UV/visible spectrometer was used to detect the absorption spectrum of the sample. The sample was dissolved in chloroform for solution state measurement. The sample must be prepared into a thin film for solid state measurement. Preparation steps of thin film samples include: preparing the sample with 5 wt % concentration and use the glass as the substrate, then a thin film was formed on the glass by spin coating. Then the measurement of the solid film can be performed. The absorption spectrum and electrochemistry properties of the sample are shown in Table 2.

TABLE 2
Absorption spectrum and electrochemistry properties of the sample

| | λₛₒₗₙ^{max} | λ_{film}^{max} | λ_{film}^{onset} | ε (10⁵ | E_{g}^{opt} | HOMO | LUMO |
|---|---|---|---|---|---|---|---|
| Material | (nm) | (nm) | (nm) | cm⁻¹M⁻¹) | (eV) | (eV) | (eV) |
| N1 | 988 | 1127 | 1319 | 1.13 | 0.94 | −5.30 | −4.36 |
| N2 | 986 | 1073 | 1294 | 1.31 | 0.96 | −5.09 | −4.13 |
| N3 | 951 | 1076 | 1253 | 1.25 | 0.99 | −5.12 | −4.13 |
| Comparative Example 1 | 744 | 830 | N.A. | N.A. | 1.3 | −5.4 | −4.0 |
| Comparative Example 2 | 814 | 920 | N.A. | N.A. | 1.2 | −5.3 | −4.1 |
| Comparative Example 3 | 875 | 995 | N.A. | N.A. | 1.1 | −5.2 | −4.1 |

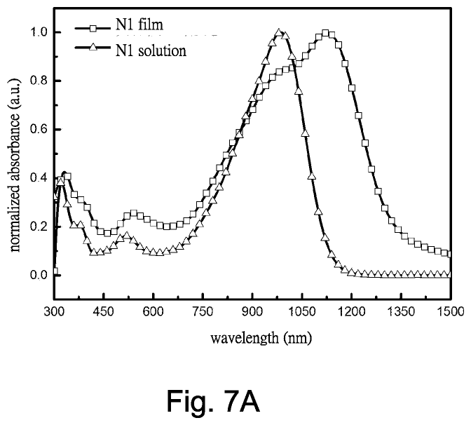

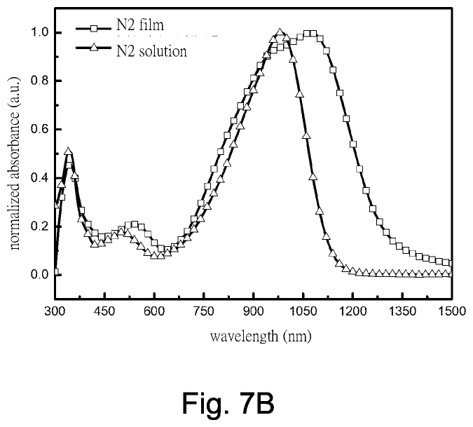

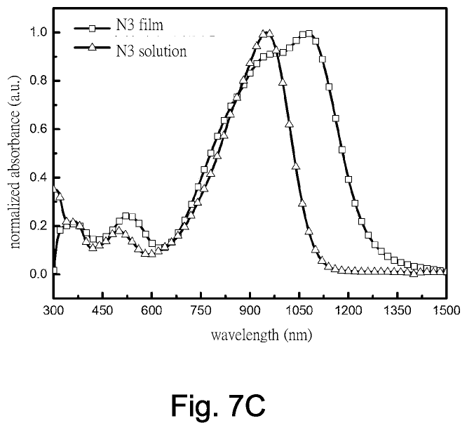

Please refer to FIG. 7A, 7B, and 7C, which show the experimental result of the absorption spectrum of the organic semiconducting compound according to the present invention. As shown in the figures, the materials N1, N2 and N3 have good performance in the absorption spectrum. The maximum absorption values of their thin film state are located at 1127, 1073 and 1076 nm, respectively. The onset absorption values are located at 1319, 1294 and 1253 nm, respectively. According to the thin film state absorption spectrum, it can be observed that it has good absorption properties at 700-1300 nm. Its optical properties not only exceed the designed 1000 nm, but also extend to 1300 nm. The applications will be more extensive in the near-infrared region. Comparative Example 1, Comparative Example 2 and Comparative Example 3 are from ACS Energy Lett. 2019, 4, 1401-1409. The thin film state absorption maximum value of Comparative Example 1 (CTIC-4F), Comparative Example 2 (CO1-4F) and Comparative Example 3 (COTIC-4F) locate at 830, 920 and 995 nm only, limiting its application range to 300-1100 nm.

The test method for OPD performance is described as follows:

The pre-patterned ITO-coated glass with sheet resistance was used as the substrate. Ultrasonic vibration treatments in neutral detergent, deionized water, acetone, and isopropyl alcohol are performed in sequence, cleaning for 15 minutes in each step. The cleaned substrate was further treated with UV-O₃ cleaner for 15 minutes. Spin-coat AZO (Aluminum-doped zinc oxide nanoparticles) on the ITO substrate at a spin rate of 2000 rpm for 40 seconds, and then bake it in the air at 120° C. for 5 minutes. An active layer solution was prepared in o-xylene (the weight ratio of donor polymer:acceptor small molecule is 1:1). The polymer concentration is 5-30 mg/ml. In order to completely dissolve the polymer, the active layer solution should be stirred on a hot plate at 100° C. for at least 3 hours and filtered with a PTFE filter membrane (pore size 0.45˜1.2 μm). Then the active layer solution should be further heated for 1 hour. Afterwards, the solution was cooled to the room temperature before coating. The film thickness was in range 100 to 300 nm by controlling spin rate. The mixed film was then annealed at 100° C. for 5 minutes and then transferred to the evaporator. Under vacuum plating of 3×10 ⁻⁶ Torr, deposit a thin layer of molybdenum trioxide (8 nm) as the hole transport layer. A Keithley™ 2400 source meter instrument was used to record the dark current (J_{d}, bias voltage −8 V) in the absence of light. Here, a standard silicon diode with a KG5 filter was used as a reference cell to calibrate the light intensity so that the mismatched parts of the spectrum are consistent. To measure the external quantum efficiency (EQE), an external quantum efficiency meter was used with a measurement range of 300˜1800 nm (bias voltage 0˜−8 V). To calibrate the light source, silicon (300˜1100 nm) and germanium (1100˜1800 nm) were adopted.

The current densities and external quantum efficiencies of the samples are shown in Table 3, which shows the test results of the electrical tests of the organic optoelectronic device using the organic semiconducting compound.

TABLE 3
Electrical tests of the organic optoelectronic device
using the organic semiconducting compound

| | | | | Dark | Detectivity | Detectivity | Detectivity |
|---|---|---|---|---|---|---|---|
| | | | | current J_{d} | D* (Jones) | D* (Jones) | D* (Jones) |
| Donor | Acceptor | Solvent | Bias | (A/cm²) | @1100 nm | @1150 nm | @1200 nm |
| Polymer | N1 | O-xylene | −2 V | 4.67 × 10⁻⁸ | 6.45 × 10¹⁰ | 4.51 × 10¹⁰ | 9.97 × 10⁸ |
| 14 | | | −4 V | 3.99 × 10⁻⁷ | 6.46 × 10¹⁰ | 4.75 × 10¹⁰ | 2.15 × 10¹⁰ |
| | | | −8 V | 8.28 × 10⁻⁶ | 4.90 × 10¹⁰ | 4.10 × 10¹⁰ | 2.35 × 10¹⁰ |

Comparative example

| | | | | | | | |
|---|---|---|---|---|---|---|---|
| PTB7- | CTIC- | Chloro- | −3 V | 5.4 × 10⁻⁶ | 1 × 10⁸ | N.A. | N.A. |
| Th | 4F¹ | benzene | | | | | |
| PTB7- | CO1-4F¹ | Chloro- | −3 V | 8.0 × 10⁻⁵ | 5 × 10⁹ | N.A. | N.A. |
| Th | | benzene | | | | | |
| PTB7- | COTIC- | Chloro- | −3 V | 1.6 × 10⁻⁵ | 2 × 10¹⁰ | N.A. | N.A. |
| Th | 4F¹ | benzene | | | | | |

In the embodiment, the dark current and external quantum efficiency (EQE) of the organic optoelectronic device of the present invention are measured, and its responsivity (R) and detectivity (D) are calculated by the following formula:

$$R ( λ ) = E Q E \frac{λ q}{h c}$$

$$D = \frac{R}{\sqrt{2 q {J}_{d}}}$$

Wherein, λ is the wavelength, q is the elementary charge, h is Planck's constant, c is the speed of light, and J_{d} is the dark current.

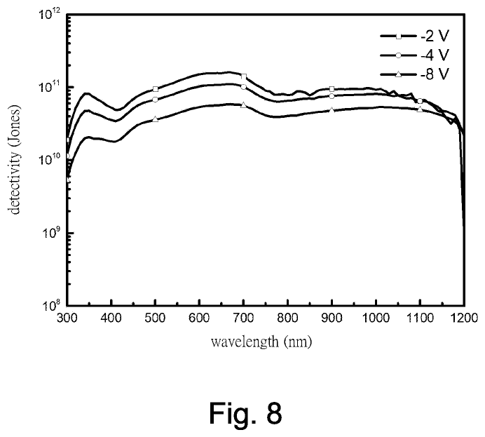

In the formulation test, we selected the same donor materials, polymer 14 (P14) and N1, and discussed their performance in the organic photodetector. For the experimental results, please refer to FIG. 8, which shows the experimental result of the detectivity of the organic optoelectronic device according to the present invention.

N1 has good solubility in both halogen solvents and non-halogen solvents. o-xylene is used as the solvent and organic photodetector devices are tested.

Please refer to FIG. 8 and Table 3. In terms of dark current performance, N1 and polymer 14 show good dark current and can be applied under different bias voltages. The dark currents are 4.67×10⁻⁸, 3.99×10⁻⁷, and 8.28×10⁻⁶ A/cm² at −2 V, −4 V, and −8 V, respectively.

The comparative examples are only applicable under lower bias voltage. As shown in Reference 1 (ACS Energy Lett. 2019, 4, 1401-1409), the material PTB7-Th is used with CTIC-4F, CO1-4F and COTIC-4F, respectively. The performances at −3 V bias are 5.4×10⁻⁶, 8.0×10⁻⁵, and 1.6×10⁻⁵, respectively.

Please refer to FIG. 8 and Table 3. From the detectivity point of view, N1 and polymer 14 can not only be applied to visible light, but also extend to near-infrared light, and can be applied under different bias voltages. When blending with polymer 14, the detectivity values at 1100 nm, 1150 nm and 1200 nm are 6.45×10¹⁰, 4.51×10¹⁰, and 9.97×10⁸ (at −2 V bias); 6.46×10¹⁰, 4.75×10¹⁰, and 2.15×10¹⁰ (at 31 4 V bias); 4.90×10¹⁰, 4.10×10¹⁰, and 2.35×10^{1°} (at −8 V bias), respectively.

The materials currently in the literature, such as Reference 1, can only be applied in 300-1100 nm. In addition, the reference uses the halogen solvent chlorobenzene in the manufacturing process. The halogen solvent is not friendly to the environment and is harmful to the human body. It will be a major obstacle in the commercialization process of the product.

The present invention develops a new type of organic semiconducting compound, and its light absorption range is extended to 1300 nm. The present invention also provides a new organic optoelectronic device, which contains the organic semiconducting compound of the present invention and has good detectivity at 1100-1200 nm. Compared with the reference literature, the present invention can be applied in the range of more than 1100 nm. In addition, non-halogen solvents are used in the manufacturing process, which can effectively reduce the impact of solvents on the environment and human body. Compared with the reference literature, the commercial value of the present invention is higher.

According to the embodiments described above, the present invention provides an organic semiconducting compound and the organic optoelectronic device using the same, in particular an n-type organic semiconducting compound. When the structure of the organic semiconducting compound according to the present invention is used as an organic optoelectronic device, it can use environmentally friendly non-halogen solvents and has good photoresponse and detectivity in the near-infrared region of 1100 nm, 1150 nm, and 1200 nm.

1. An organic semiconducting compound, having the following structure: 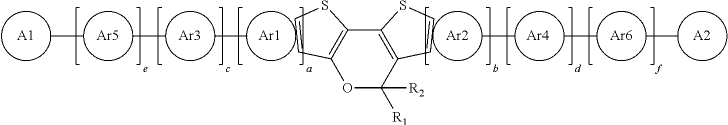
wherein Ar1 and Ar2 are aryl or heteroaryl groups with 5-20 ring atoms, which are monocyclic or fused rings;
Ar3 and Ar4 are aryl or heteroaryl groups with 5-20 ring atoms, which are monocyclic or fused rings and are substituted by one or more functional group containing heteroatoms;
Ar5 and Ar6 are vinyl groups;
A1 and A2 are monocyclic or polycyclic groups with 5-20 ring atoms, which contain one or more ketone group and one or more electron-withdrawing group;
R₁ and R₂ are independently selected from the group consisting of C1˜C30 alkyl group, C1˜C30 silyl group, C1˜C30 alkoxy group, C1˜C30 alkylthio group, C1˜C30 haloalkyl group, C2˜C30 ester group, C1˜C30 alkylaryl group, C1˜C30 alkyl heteroaryl group, C1˜C30 silylaryl group, C1˜C30 silyl heteroaryl group, C1˜C30 alkoxyaryl group, C1˜C30 alkoxyheteroaryl group, C1˜C30 alkylthioaryl group, C1˜C30 alkylthioheteroaryl group, C1˜C30 haloalkylaryl group, C1˜C30 haloalkylheteroaryl group, C1˜C30 ester aryl group, and C1˜C30 ester heteroaryl group;
a and b are selected from 0 or 1, respectively, and a+b≤1;
c and d are selected from 1 or 2, respectively; and
e and f are selected from the integers between 0 and 2, respectively, and e+f≥1.

2. The organic semiconducting compound according to claim 1, wherein Ar1 is:

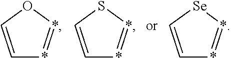

3. The organic semiconducting compound according to claim 1, wherein Ar2 is:

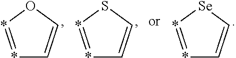

4. The organic semiconducting compound according to claim 1, wherein Ar3 and Ar4 are: 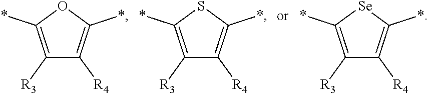
R₃ and R₄ are independently selected from the group consisting of H, C1˜C30 silyl group, C1˜C30 alkoxy group, C1˜C30 alkylthio group, C1˜C30 haloalkyl group, C2˜C30 ester group, C1˜C30 alkylaryl group, C1˜C30 alkyl heteroaryl group, C1˜C30 silylaryl group, C1˜C30 silyl heteroaryl group, C1˜C30 alkoxyaryl group, C1˜C30 alkoxyheteroaryl group, C1˜C30 alkylthioaryl group, C1˜C30 alkylthioheteroaryl group, C1˜C30 haloalkylaryl group, C1˜C30 haloalkylheteroaryl group, C1˜C30 ester aryl group, and C1˜C30 ester heteroaryl group, wherein at least one of R₃ and R₄ is not H.

5. The organic semiconducting compound according to claim 1, wherein organic semiconducting compound is selected from the group consisting of the following formulae:

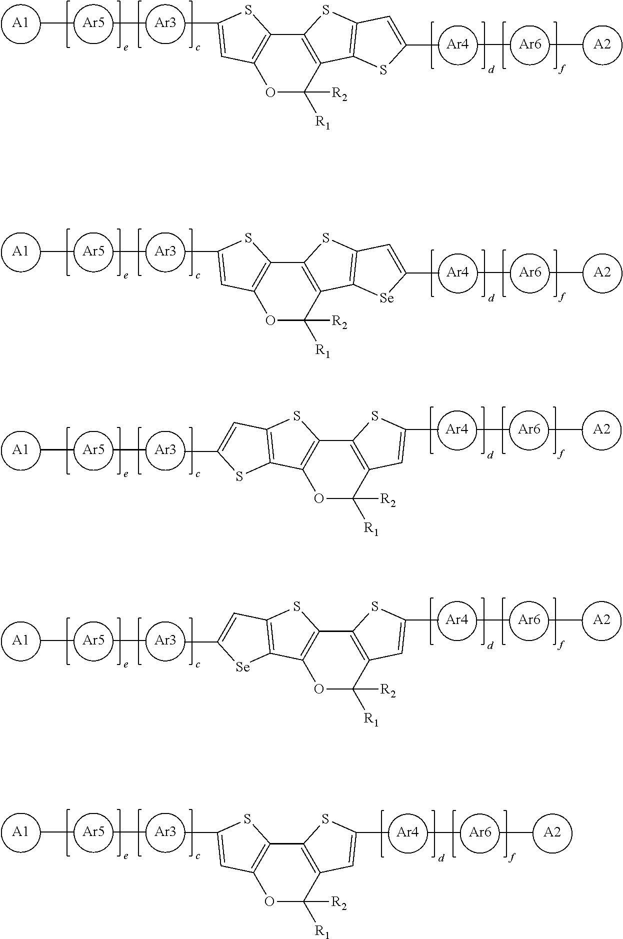

6. The organic semiconducting compound according to claim 1, wherein A1 and A2 are independently selected from the group consisting of the following formulae: 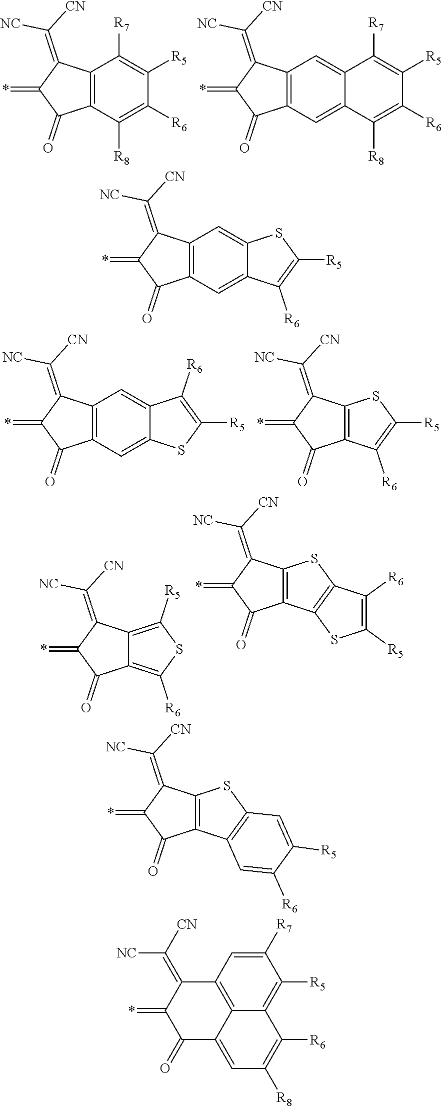
R₅, R₆, R₇, and R₈ are independently selected from the group consisting of C1˜C30 alkyl group, C1˜C30 silyl group, C1˜C30 alkoxy group, C1˜C30 alkylthio group, C1˜C30 haloalkyl group, halogen, hydrogen atom, and cyano group.

7. A composition, which includes an n-type organic semiconducting compound and a p-type organic semiconducting compound, wherein the n-type organic semiconducting compound is the organic semiconducting compound of claim 1, and the p-type organic semiconducting compound is a polymer.

8. The composition according to claim 7, wherein the p-type semiconducting compound is selected from the group consisting of the following formulae:

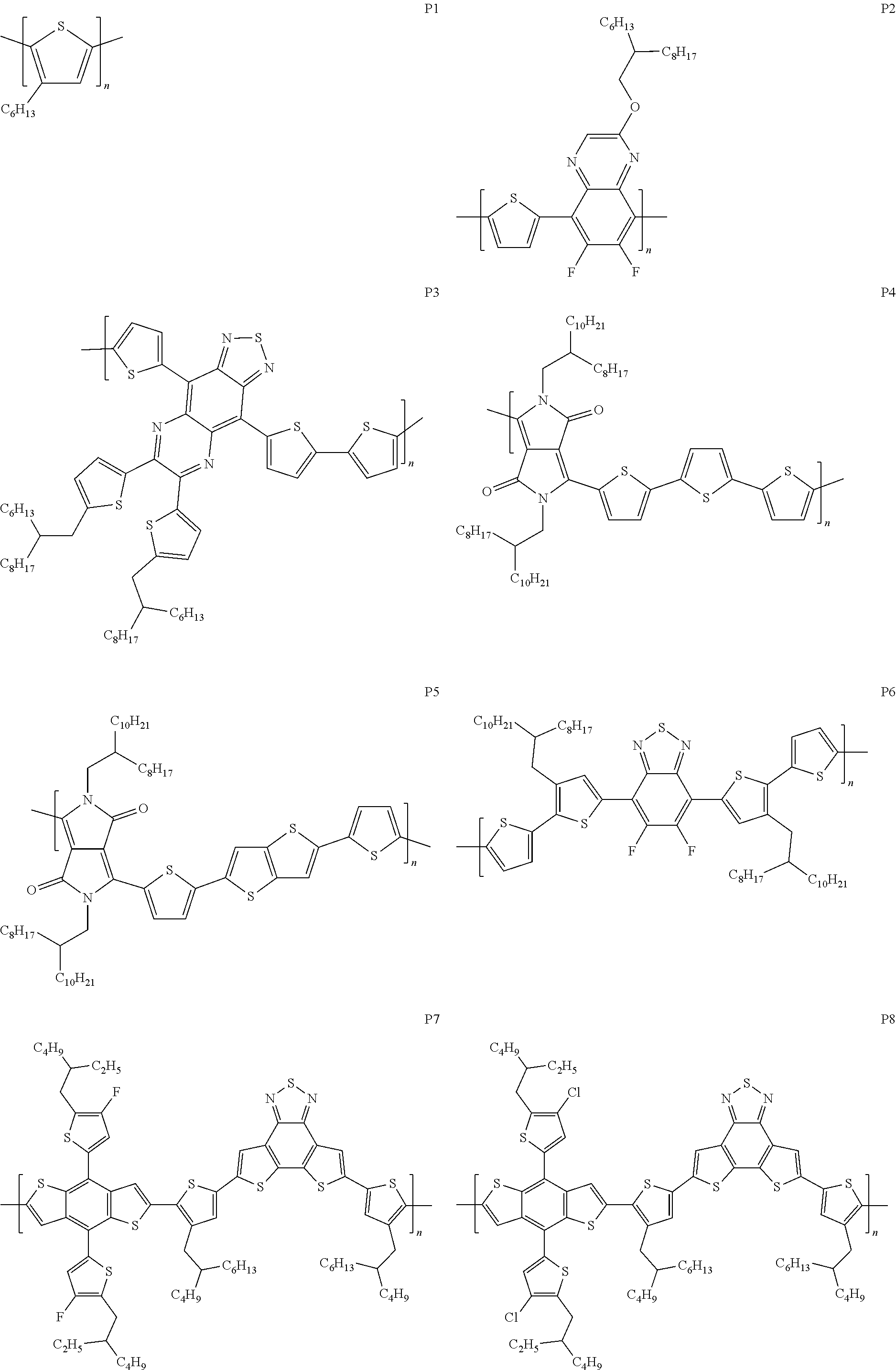

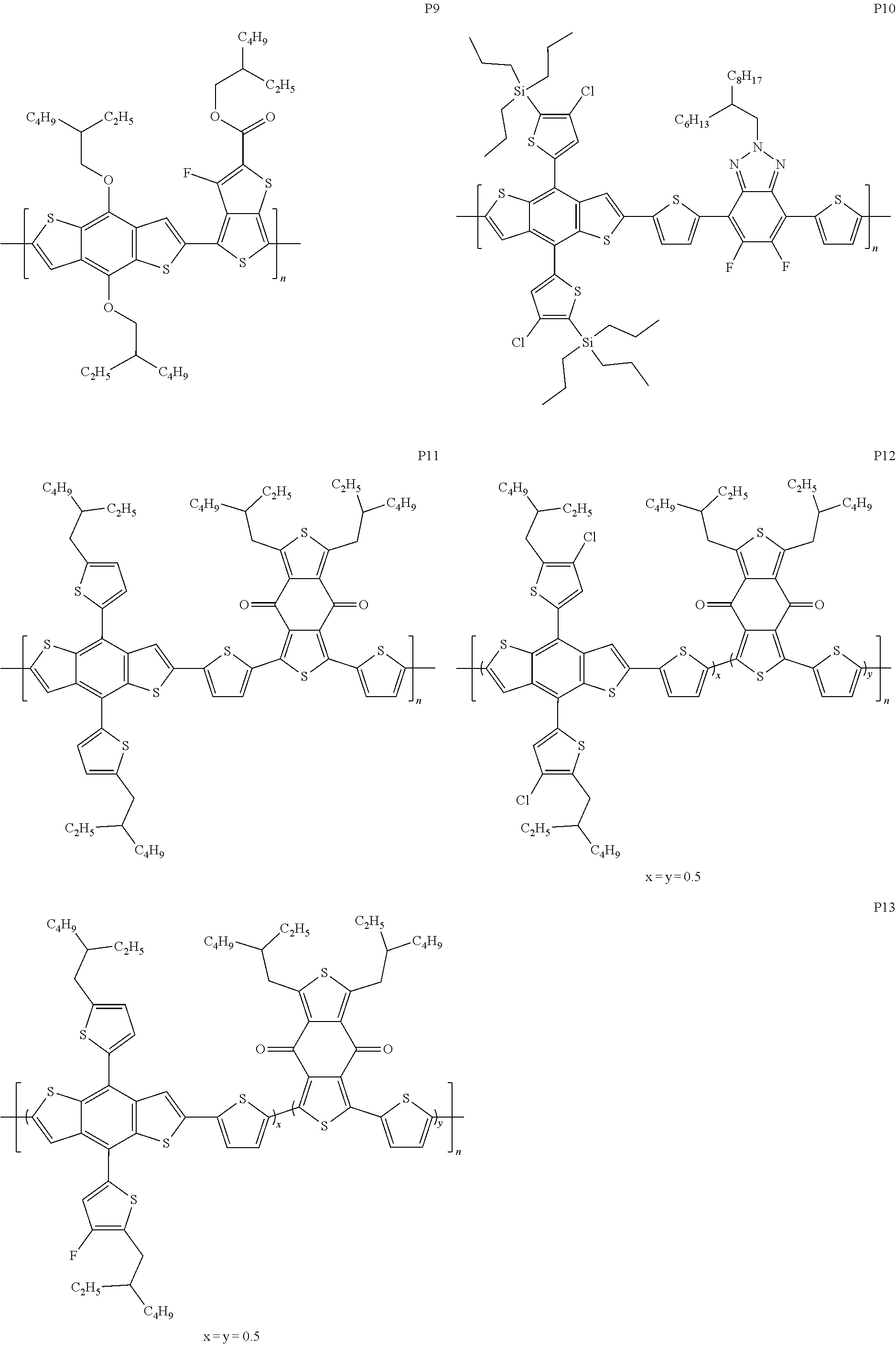

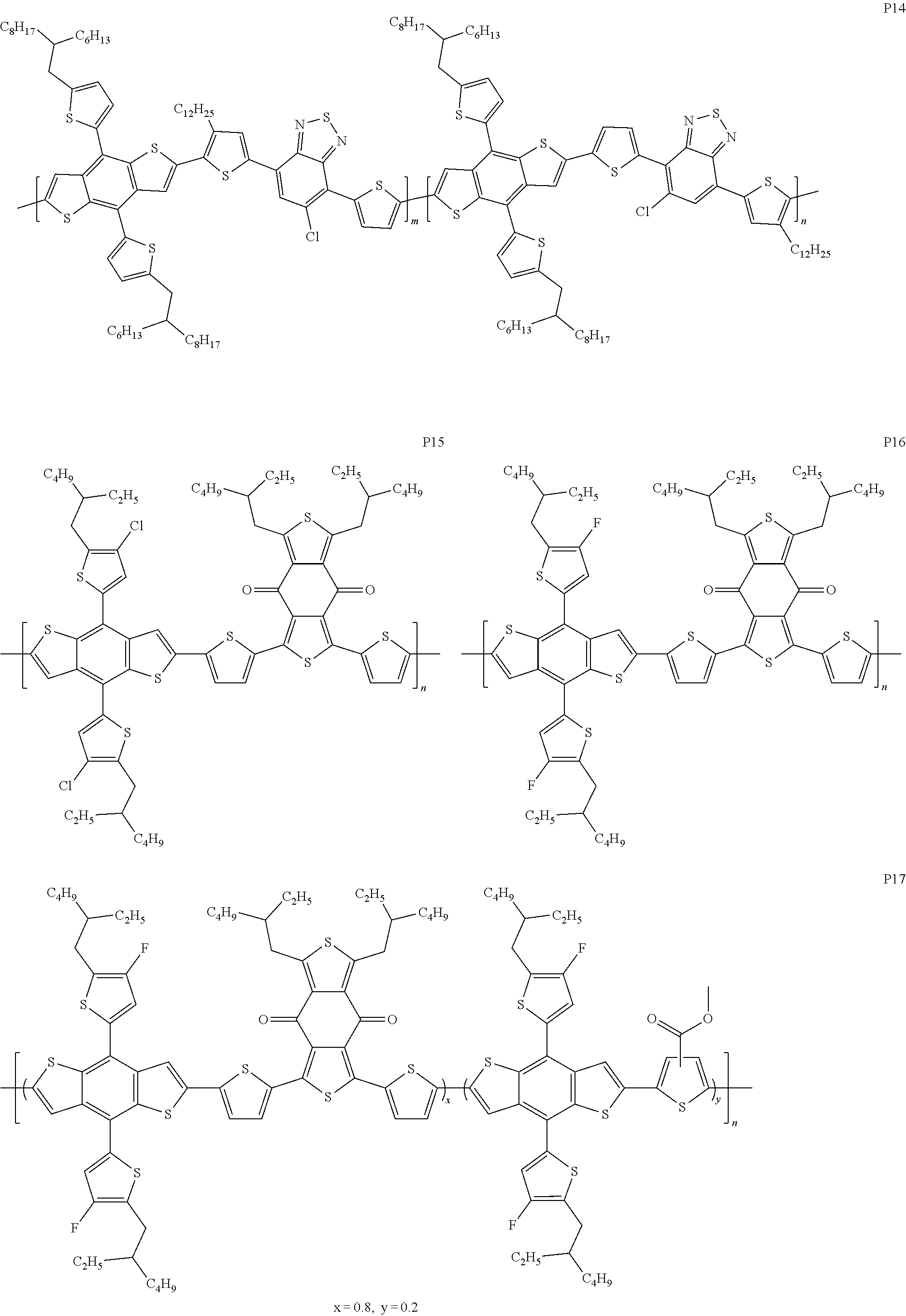

9. An organic optoelectronic device, comprising:
a substrate;
an electrode module disposed on substrate, and including a first electrode and a second electrode; and
an active layer disposed between the first electrode and the second electrode, and the material of the active layer comprises organic semiconducting compound of claim 1 or the composition of claim 7;
wherein at least one of the first electrode and the second electrode is transparent orsemi-transparent.

10. The organic optoelectronic device according to claim 9, wherein the first electrode, the active layer, and the second electrode are disposed sequentially from the bottom up on the substrate.

11. The organic optoelectronic device according to claim 9, wherein the second electrode, the active layer, and the first electrode are disposed sequentially from the bottom up on the substrate.

12. The organic optoelectronic device according to claim 9, further comprising a first carrier transport layer and a second carrier transport layer, wherein the first carrier transport layer is disposed between the first electrode and the active layer, and the second carrier transport layer is disposed between the active layer and the second electrode.

13. The organic optoelectronic device according to claim 9, further comprising a first carrier transport layer and a second carrier transport layer, wherein the first carrier transport layer is disposed between the second electrode and the active layer, and the second carrier transport layer is disposed between the active layer and the first electrode.
